(19) United States
(12) Patent Application Publication
(10) Pub. No.: US 2006/0220263 A1
(43) Pub. Date: Oct. 5, 2006

(54) Semiconductor device to be applied to various types of semiconductor package

(75) Inventors: Toshihiro Waki, Tokyo (JP); Sadayuki Okuma, Tokyo (JP)

Correspondence Address: FOLEY AND LARDNER LLP;SUITE 500, 3000 K STREET NW, WASHINGTON, DC, 20007, US

(73) Assignee: ELPIDA MEMORY, INC.

(21) Appl. No.: 11/392,679

(22) Filed: Mar. 30, 2006

(30) Foreign Application Priority Data
Mar. 31, 2005 (JP) 2005-100720

(51) Int. Cl. H01L 23/48

(52) U.S. Cl. 257/786

(57) ABSTRACT

A plurality of first pads for bonding is arranged in a central portion of a semiconductor device in a longitudinal direction of the device. In an edge portion of the semiconductor device, a plurality of second pads for bonding is arranged in the longitudinal direction of the device. The first pad and the second pad are connected by a wiring.

### BACKGROUND OF THE INVENTION

1. Field of the Invention

The present invention relates to a semiconductor device, such as DRAM (Dynamic Random Access Memory).

2. Description of the Related Art

For semiconductor devices like DRAM, there are various packages, such as FBGA (Fine pitch Ball Grid Array) and TSOP (Thin Small Outline Package). FIG. 1 shows a cross-sectional view of an example of the structure of FBGA, and FIG. 2 shows a cross-sectional view of an example of the structure of TSOP.

As shown in FIG. 1, in FBGA, electric wiring board 102 is arranged around semiconductor device 101, and external terminals 103 shaped in balls are connected to the back surface of electric wiring board 102. External terminal 103 is connected to bonding pad 105 of semiconductor device 101 through bonding wire 104 connected to the front surface of electric wiring board 102.

On the other hand, in TSOP, when the LOC (Lead On Chip) structure is used, lead frame 106 is extended from the front surface of semiconductor device 101 to the outside of the package. Bonding pad 105 on the front surface of semiconductor device 101 and the end of lead frame 106 are connected by bonding wire 104. Incidentally, the LOC structure is widely used for DRAM, with the size reduction of packages and the increasing speed and increasing packing density of memories.

As is apparent from FIGS. 1 and 2, in FBGA, the bonding pad is arranged on the edge portion (peripheral portion) of the semiconductor device. In TSOP, the bonding pad is arranged on the central portion of the semiconductor device.

FIG. 3 shows an example of a typical pad arrangement in DRAM. As shown in FIG. 3, in DRAM, memory regions 201 are formed on the semiconductor device other than the central portion, and peripheral circuit region 202 is arranged along the center line of the semiconductor device. For that reason, when TSOP is manufactured, DRAM of the typical pad arrangement, shown in FIG. 3, can be used as it is.

However, in packages of FBGA, since the bonding pads exist in the central portion, wires for connecting the bonding pads and the electric wiring board are long. Therefore, bonding becomes difficult. Further, FBGA provides a type in which a semiconductor device is put on the other semiconductor device. Therefore, a semiconductor device is required, in which bonding pads are not arranged in the central portion.

For this reason, for packages of FBGA, a semiconductor device has been newly developed, in which bonding pads 203 are arranged in the end portion (peripheral portion) of the semiconductor device, as shown in FIG. 4.

Japanese Patent Laid-Open No. 2001-358305 discloses the semiconductor device in which pads are arranged on the central portion and the peripheral portion of the front surface of the semiconductor device.

As described above, each semiconductor device having pad arrangements must be developed for each type of package. Therefore, semiconductor devices must be designed and managed for every type of package, and thus the design and management of products become complicated.

The semiconductor device disclosed in Japanese Patent Laid-Open No. 2001-358305 is a semiconductor device of a flip chip type. The semiconductor device is characterized in that pads on which solder bumps are mounted are arranged in the central portion of the front surface of the semiconductor device and dummy pads for testing are arranged in the peripheral portion of the semiconductor device. In other words, the pads of the semiconductor device are not arranged in the central portion and the peripheral portion of the semiconductor device in order to correspond to a plurality of types of package assemblies with one type of semiconductor device. Also, the pads in the peripheral portion of the semiconductor device are used only for testing, and are not used for bonding.

### SUMMARY OF THE INVENTION

Accordingly, in view of the above-mentioned problems, it is an object of the present invention to provide one semiconductor device that can address various types of package assemblies.

According to the present invention, a plurality of first pads for bonding is arranged in the central portion of the semiconductor device, and a plurality of second pads for bonding is arranged in the edge portion of the semiconductor device. Also, the first pads and the second pads are connected by wirings.

In the semiconductor device, for example, a package that requires the pads in the central portion, e.g., TSOP, can be assembled by using the first pads. Also, a package that requires the pads in the edge portion, e.g., FBGA, can be assembled by using the second pads.

Therefore, according to the present invention, the plurality of types of package assemblies can be addressed by one type of semiconductor devices.

The above and other objects, features, and advantages of the present invention will become apparent from the following description with reference to the accompanying drawings, which illustrate examples of the present invention.

### BRIEF DESCRIPTION OF THE DRAWINGS

FIG. 1 is a cross-sectional view showing an example of the structure of FBGA;

FIG. 2 is a cross-sectional view showing an example of the structure of TSOP;

FIG. 3 is a plan view showing bonding pads of a conventional semiconductor device;

FIG. 4 is a plan view showing bonding pads of a conventional semiconductor device;

FIG. 5 is a plan view showing a semiconductor device according to an embodiment of the present invention;

FIG. 6 is a plan view showing a semiconductor device according to another embodiment of the present invention;

FIG. 7 is a view showing an example in which an input circuit is connected to the bonding pad of the semiconductor device in FIG. 5;

FIG. 8 is a view showing an example in which an output circuit is connected to the bonding pad in the central portion of the semiconductor device in FIG. 5;

FIG. 9 is a view showing an example in which one MOS-FET for used output is divided into halves and each divided MOS-FET is respectively arranged on the bonding pad in the central portion and on the bonding pad in the edge portion of the semiconductor device in FIG. 5;

FIG. 10 is a view showing a concrete example of the method shown in FIG. 9;

FIG. 11 is a view showing a concrete example of the method shown in FIG. 9;

FIG. 12 is a view showing an example in which power source pads are added to the edge portion of the semiconductor device in FIG. 5;

FIG. 13 is a view showing an example in which the use of the first pads in the central portion of the semiconductor device are different from the use of the second pads in the edge portion of the semiconductor device and which are arranged so as to correspond to the first pads;

FIG. 14 is a view showing an example in which the first pads in the central portion and the second pads in the edge portion are not arranged in corresponding positions of the semiconductor device according to another embodiment of the present invention;

FIG. 15 is a view showing an example in which probe testing is performed for the first pads in the central portion of the semiconductor device and for the second pads in the edge portion of the semiconductor device and which are arranged so as to correspond to the first pads;

FIG. 16 is a view showing an example in which the second pads are alternately distributed in both edge portions of the semiconductor device according to another embodiment of the present invention; and

FIG. 17 is a view showing an example in which only DQ pads are arranged not only in the central portion but also in the edge portion of the semiconductor device according to another embodiment of the present invention.

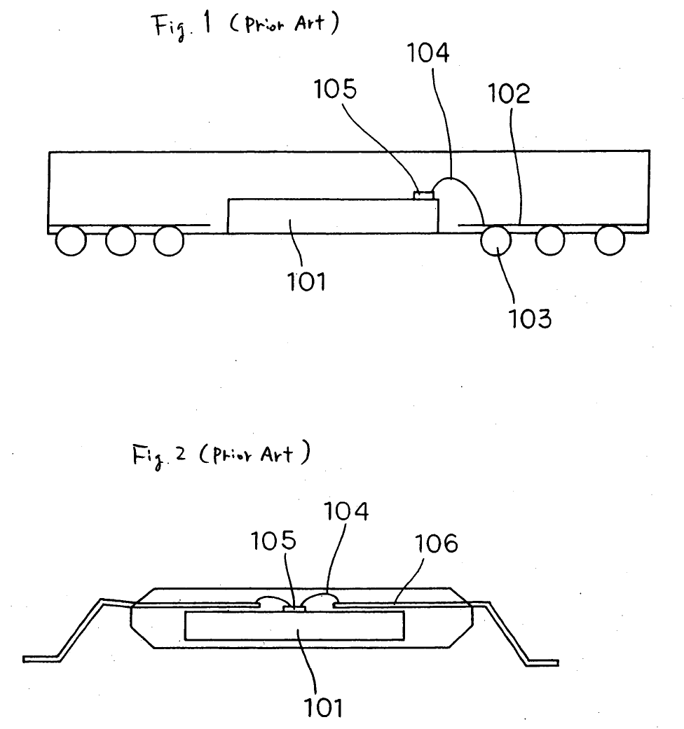

### DESCRIPTION OF THE PREFERRED EMBODIMENTS

In this description, DRAM is taken as an example of a semiconductor device.

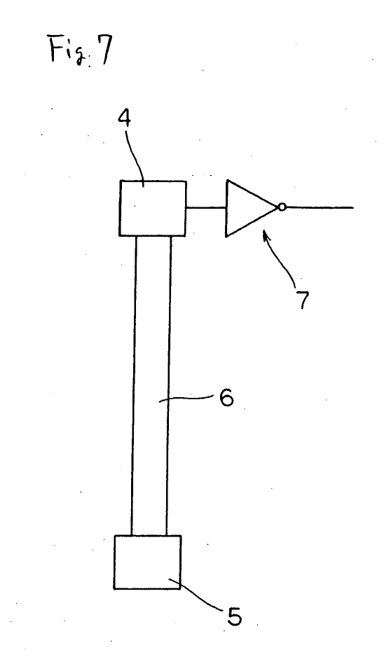

FIG. 5 is a plan view showing a semiconductor device according to an embodiment of the present invention.

The semiconductor device shown in FIG. 5 is provided with a memory and a control circuit that performs reading from the memory and writing to the memory, on a rectangular semiconductor substrate. As shown in FIG. 5, memory region 2 is arranged except in the central portion of semiconductor device 1, and control circuit region 3 is arranged in the central portion of semiconductor device 1.

In central portion of semiconductor device 1, a plurality of first bonding pads 4 is arranged in a line in the longitudinal direction of semiconductor device 1 (X-direction in FIG. 5). In one edge portion out of two edge portions in the lateral direction of semiconductor device 1 (Y-direction in FIG. 5), a plurality of second bonding pads 5 is arranged in a line in the longitudinal direction of semiconductor device 1. First bonding pads 4 and second bonding pads 5 that are relatively positioned in the lateral direction of semiconductor device 1 are connected by wirings 6. With this arrangement, first bonding pads 4 and second bonding pads 5 are identical functional pads. In this description, the identical functional pads mean that, for example, when first bonding pads 4 are signal input pads, second bonding pads 5 are also signal input pads. In FIG. 5, the pads are completely arranged in the straight line, however, needless to say, though pads are somewhat shifted from the straight line, that does not represent a deviation from the present invention.

Incidentally, in FIG. 5, symbols of A, B, C and D are written in squares drawn as first bonding pads 4 and second bonding pads 5. The pad of symbol A is used as VDD (power source on supply side), the pad of symbol B is used as VSS (power source on ground side), the pad of symbol C is used for DQ (input or output of signal), and the pad of symbol D is used for AP (only signal input). As is apparent from FIG. 5, the same symbol is written in first bonding pad 4 and second bonding pad 5 that are connected by wiring 6. In other words, first bonding pad 4 and second bonding pad 5 that are connected by wiring 6 are identical functional pads.

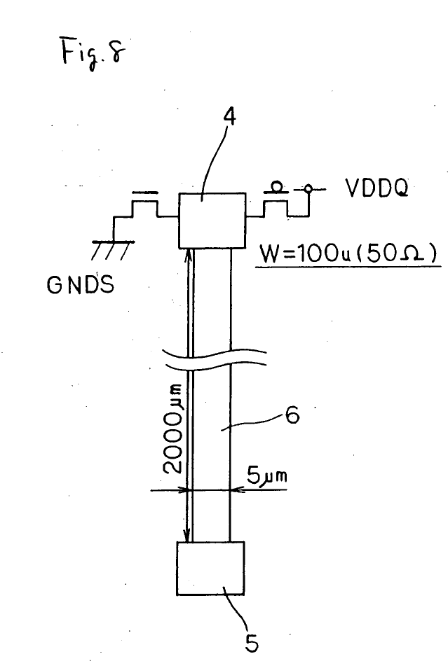

Further, wiring 6 is formed in a straight line on memory region 2 in order to connect first bonding pad 4 and second bonding pad 5 in the shortest distance, as shown in FIG. 5. In DRAM, since a memory array usually exists in memory region 2 between bonding pads 4, 5, wiring 6 is suitably arranged in another wiring layer other than the wiring layer of the memory array. For example, layers from the surface of a semiconductor substrate to the second wiring layer are used for wiring of memory cells, a third wiring layer is newly added and the wirings connecting bonding pads 4, 5 are arranged in the third wring layer. Alternatively, no new wiring layer is arranged, and wirings 6 may be routed to connect bonding pads 4, 5 while avoiding wirings (not shown) in memory region 2, as shown in FIG. 6. However, in this arrangement, the wirings between bonding pads 4, 5 become longer and wiring resistance is increased. Therefore, this arrangement is not suitable to high-speed operation and is effective only in semiconductor devices that operate at low speed.

With semiconductor device 1, which is described above, packages that require central pads, e.g., TSOP, can be assembled by using first bonding pads 4. Also, packages that require edge pads, e.g., FBGA, can be assembled by using second bonding pads 5. In other words, according to this embodiment, various types of packages can be addressed by one type of semiconductor device.

Next, explanations are given of a circuit that is connected to bonding pads 4, 5.

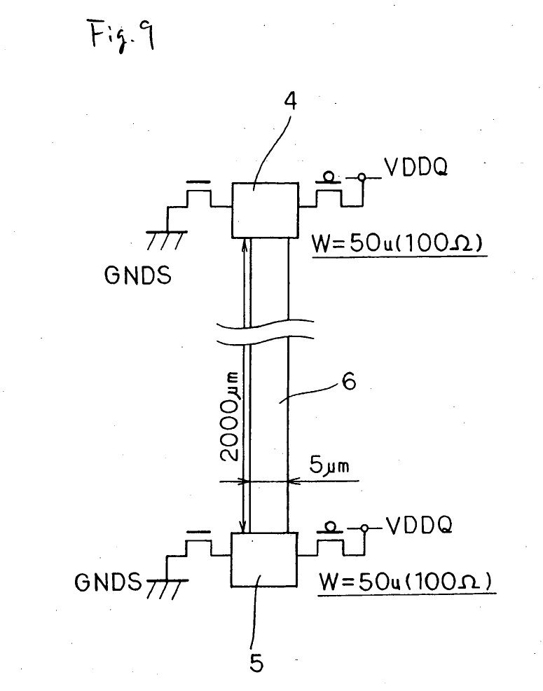

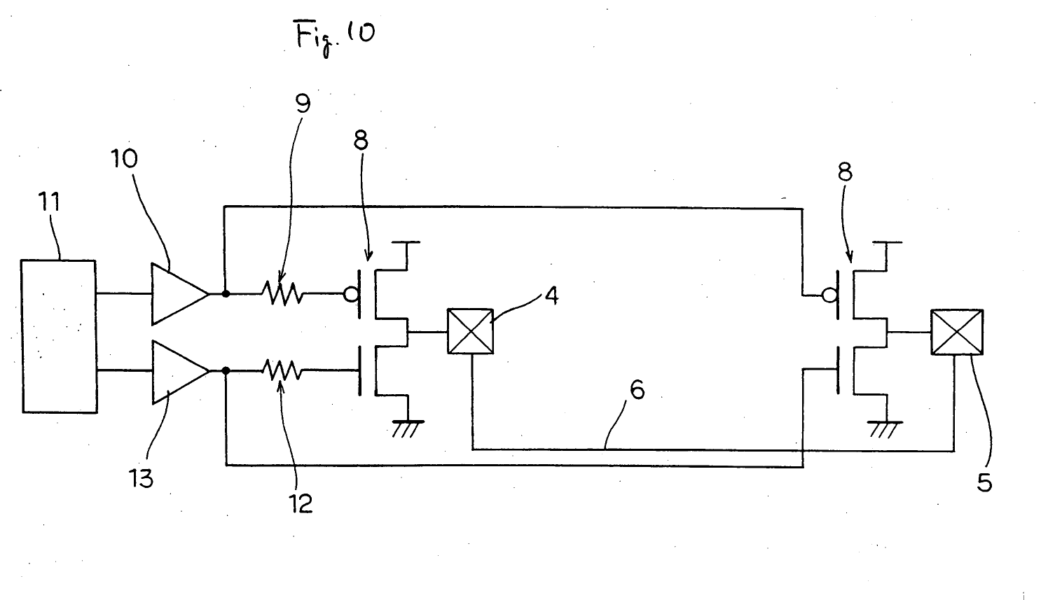

Since two bonding pads 4, 5 are electrically equivalent, the desired circuit may be connected to either of bonding pad 4 or pad 5. For example, as shown in FIG. 7, input circuit 7 is arranged for only first bonding pad 4 arranged in the central portion of semiconductor device 1. However, since an output circuit is sensitive to the resistance of wiring 6 between bonding pad 4 and pad 5, there is little possibility that desired characteristics are satisfied when the output circuit is connected to only either bonding pad 4 or pad 5. For example, as shown in FIG. 8, an output MOS-FET is arranged as an output circuit only for first bonding pad 4 arranged in the central portion of semiconductor device 1. In this case, output characteristics are considerably different between the case in which a wire is bonded to first bonding pad 4 in the central portion and the case in which a wire is bonded to second bonding pad 5 in the edge portion. The reason is described below. In FIG. 8, when the distance of wiring 6 between bonding pad 4 and pad 5 is about 2000 μm, the width of wiring is about 5 μm, and the sheet resistance of wiring 6 is about 100Ω/□, the resistance of wiring 6 is about 40Ω. The resistance of the output MOS-FET depends on the constant of MOS (for example, thickness [width] W of the gate between the drain and the source). Assuming that the resistant value is 50Ω (W=100 μm), when first bonding pad 4 is used, the output resistance is 50Ω because only the resistance of the output MOS-FET has an effect on the output resistance. Also, when second bonding pad 5 is used, the output resistance is 90Ω because both the resistance of the output MOS-FET and the resistance of wiring 6 have effects on the output resistance. Accordingly, the difference of 1.8 times occurs. To prevent this difference, the following methods are considered;

a) thickening the wiring width of wiring 6;

b) enabling the thickness (width) of the gate in the output MOS-FET to be changed by a fuse or the like, and increasing width W of the gate (constant of MOS) and reducing the resistance of the output MOS-FET when second bonding pad 5 is used; and

c) dividing the one MOS-FET in halves and arranging each divided MOS-FET for first bonding pad 4 and second bonding pad 5 (FIG. 9).

In method a), since the pin capacity increases, this method may be applied within the range that satisfies the pin capacity standard. As another example of this method, for instance, first bonding pad 4 and second bonding pad 5 may be connected by a wiring. This example is available to a semiconductor device having a sufficiently large pad area such that a plurality of wires can be bonded in one bonding pad.

In method b), since the size of output MOS-FET is changed in size, this method is available when semiconductor device 1 has sufficient area. Also, in this method, whether first bonding pad 4 in the central portion is used or whether second bonding pad 5 in the edge portion is used must be set, by a fuse before a package is assembled or by a bonding option while a package is assembled. Incidentally, the bonding option is to change the setting in a specific pad connection condition (connection to VSS or VDD pads, or the like).

In method c), when the one MOS-FET used for output is divided (portioned) in halves, the resistance of divided output MOS-FET becomes twice. Assuming that the resistance value is 100Ω (W=50 μm), when the distance of wiring 6 between bonding pad 4 and pad 5 is about 2000 μm, the width of wiring 6 is about 5 μm, and the sheet resistance of wiring 6 is about 100Ω/□, the output resistance is 58.3Ω[=(100×40)/(140+100)], in both the case in which bonding pad 4 in the central portion is used and the case in which bonding pad 5 in the edge portion is used. In other words, compared with the output resistance of the case in which the output circuit is arranged for only first bonding pad 4 and in which bonding is applied to first bonding pad 4, as shown in FIG. 8, the output resistance in the case of FIG. 9 is only 1.16 times. Therefore, when the output resistance is suppressed equally to the output resistance in the case in which the output circuit is arranged for only first bonding pad 4, and in the case in which bonding is applied to first bonding pad 4, as shown in FIG. 8, the constant of MOS, i.e., width W of the gate between the source and the drain, may be 1.16 times. With this arrangement, the output resistance can be reduced while suppressing an increase in the size of the semiconductor device.

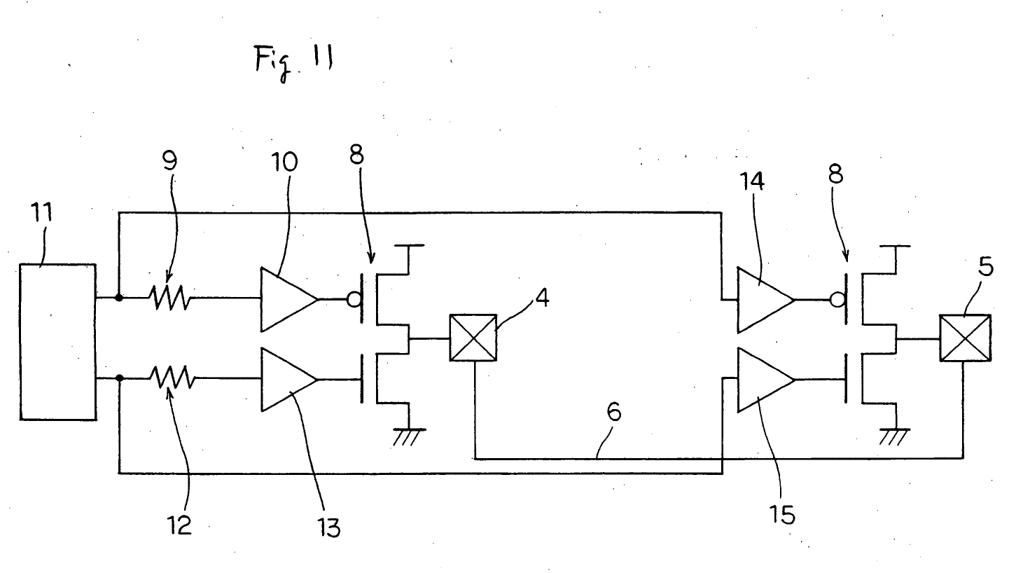

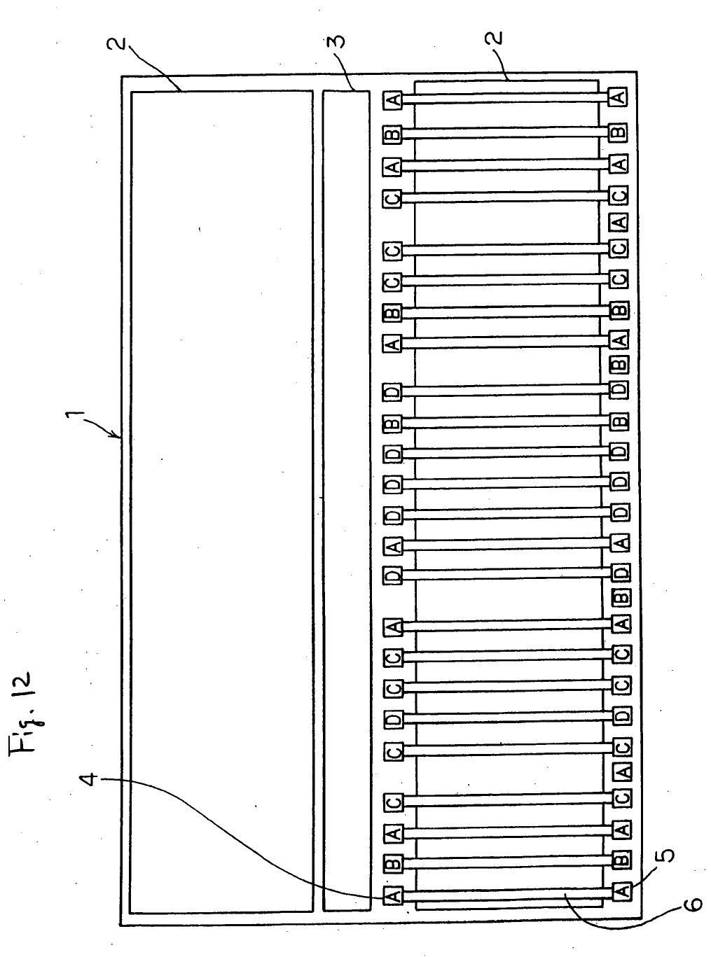

Now, FIGS. 10 and 11 show concrete examples of the above-mentioned method c).

As shown in FIGS. 10 and 11, first bonding pad 4 in the central portion of semiconductor device 1 and second bonding pad 5 in the edge portion of semiconductor device 1 are connected by wiring 6, and each divided MOS-FET 8 is connected to each of bonding pads 4, 5. Each MOS-FET 8 is provided with a P-channel transistor and an N-channel transistor that are connected in series between a power source potential and a ground potential. The drains of the P-channel transistor and the N-channel transistor in each MOS-FET 8 are connected to each of first bonding pad 4 and second bonding pad 5.

The gate of the P-channel transistor, whose drain is connected to first bonding pad 4, is connected to output control circuit 11 through resistor 9 used for delay adjustment and output buffer 10 that are connected in series. The gate of the N-channel transistor, whose drain is connected to first bonding pad 4, is also connected to output control circuit 11 through resistor 12 for delay adjustment and output buffer 13 that are connected in series. Resistor 9 or 12 used for delay adjustment is set according to the wiring resistance from output buffer 10 or 13 to MOS-FET 8 in the edge portion in order to adjust the delay from output buffer 10 or 13 to each MOS-FET 8 in the central portion and in the edge portion.

Further, in the example shown in FIG. 10, the gate of the P-channel transistor, whose drain is connected to second bonding pad 5, is connected between resistor 9 used for delay adjustment and output buffer 10 that are connected in series. Also, the gate of the N-channel transistor, whose drain is connected to second bonding pad 5, is connected between resistor 12 used for delay adjustment and output buffer 13 that are connected in series.

On the other hand, in the example in FIG. 11, the gate of the P-channel transistor, whose drain is connected to second bonding pad 5, is connected to output control circuit 11 through output buffer 14 that is equal to output buffer 10. Also, the gate of the N-channel transistor, whose drain is connected to second bonding pad 5, is connected to output control circuit 11 through output buffer 15 that is equal to output buffer 13.

According to each configuration, the same output control signal is given to MOS-FET 8 connected to first bonding pad 4 in the central portion of semiconductor device 1 and to MOS-FET 8 connected to second bonding pad 5 in the edge portion of semiconductor device 1 from one output control circuit 11 with the same timing.

In the configuration in FIG. 11, gate capacities of output buffers 10, 13, 14, 15 are smaller than that of MOS-FET 8, and the wiring delay (r=CR) becomes smaller than that of FIG. 10. Therefore, resistors 9, 12 may be omitted when their characteristics have no problem.

Next, another embodiment of the present invention is explained.

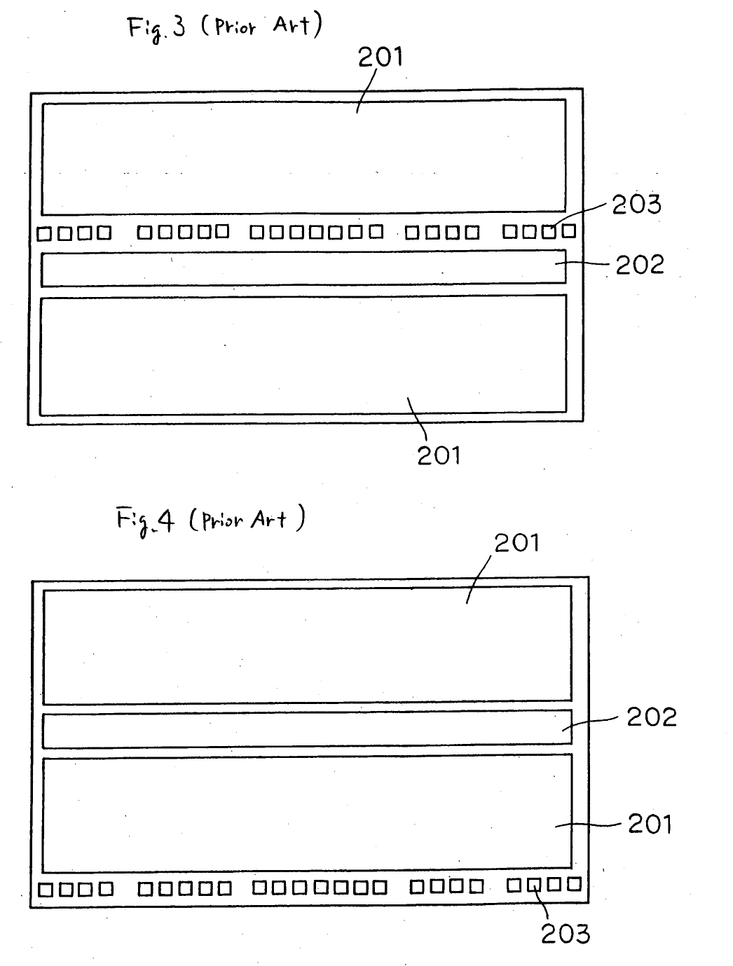

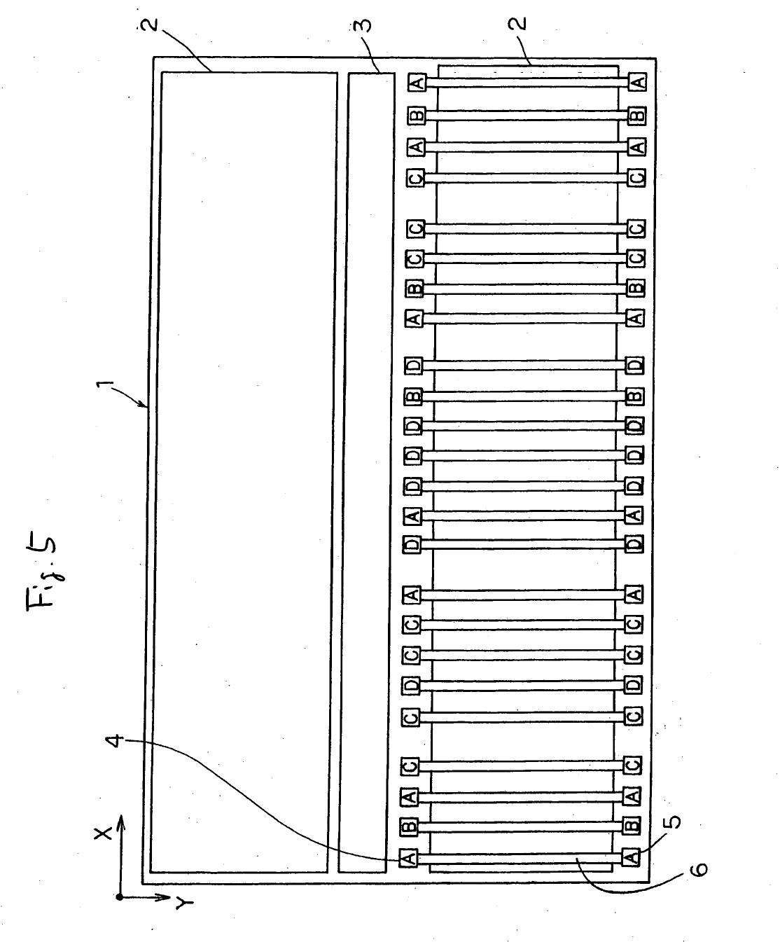

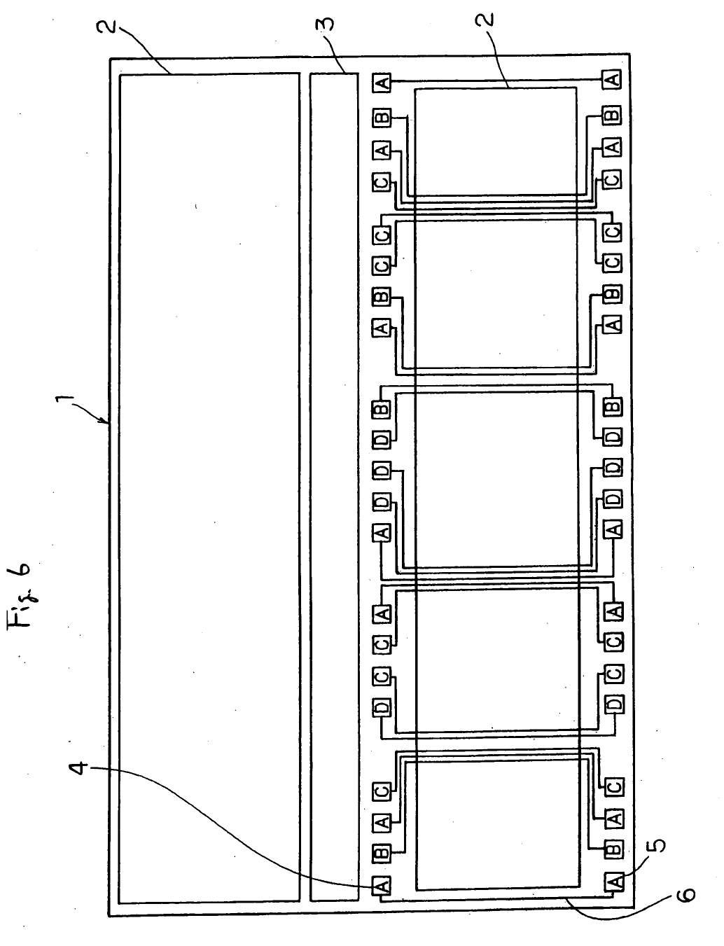

In the above-mentioned embodiment, the number of first bonding pads 4 arranged in the central portion of semiconductor device 1 is the same to the number of second bonding pads 5 arranged in the edge portion of semiconductor device 1, however, these numbers may be different. FIG. 12 shows a case in which the number of bonding pads in the edge portion is larger than that in the central portion of semiconductor device 1. As is apparent from FIG. 12, pads of symbols A and B are added to the edge portion of semiconductor device 1. As described above, pads of symbols A are used as VDD (power source on supply side) and pads of symbols B are used as VSS (power source on ground side). Regardless of DRAM having the main circuit in the central portion shown in FIG. 3, circuits partially exist in the edge portion. Therefore, a layout is used, in which pads partially exist in the edge portion. Application of the example in FIG. 12 is effective on such a layout.

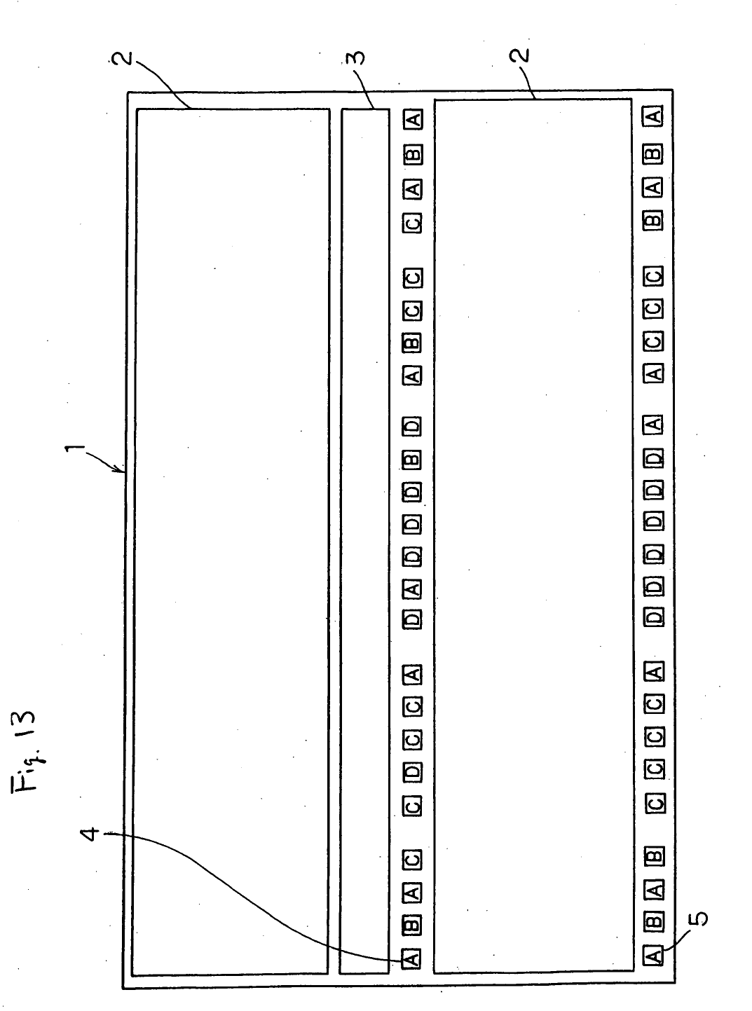

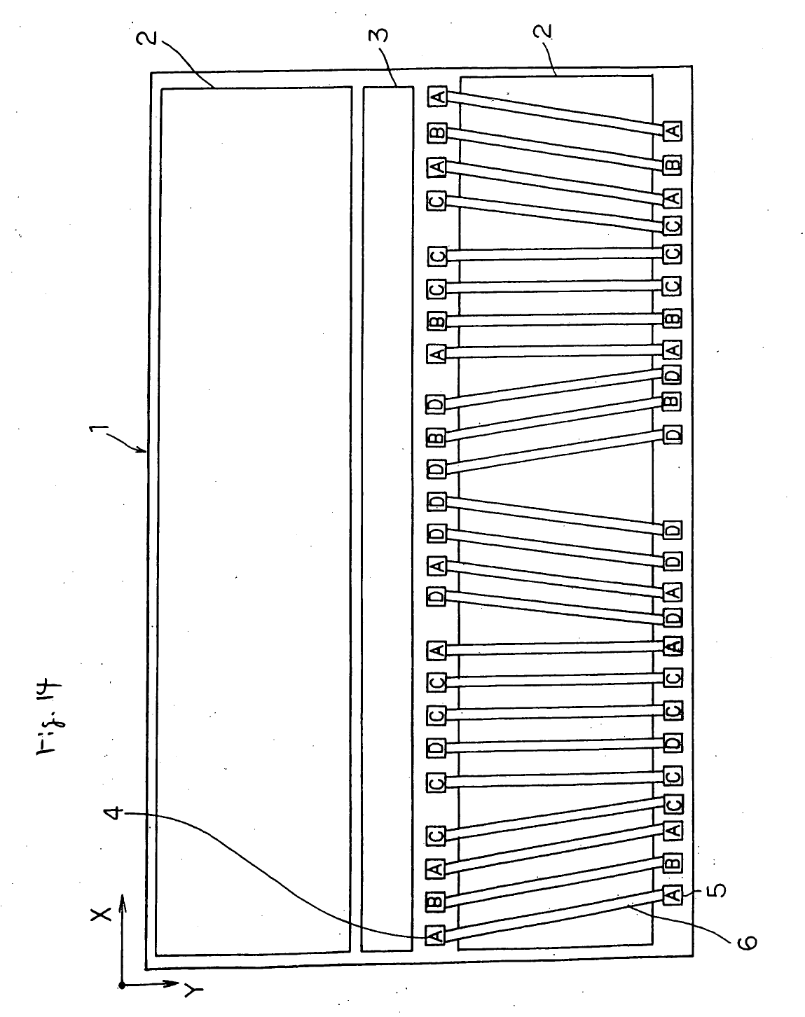

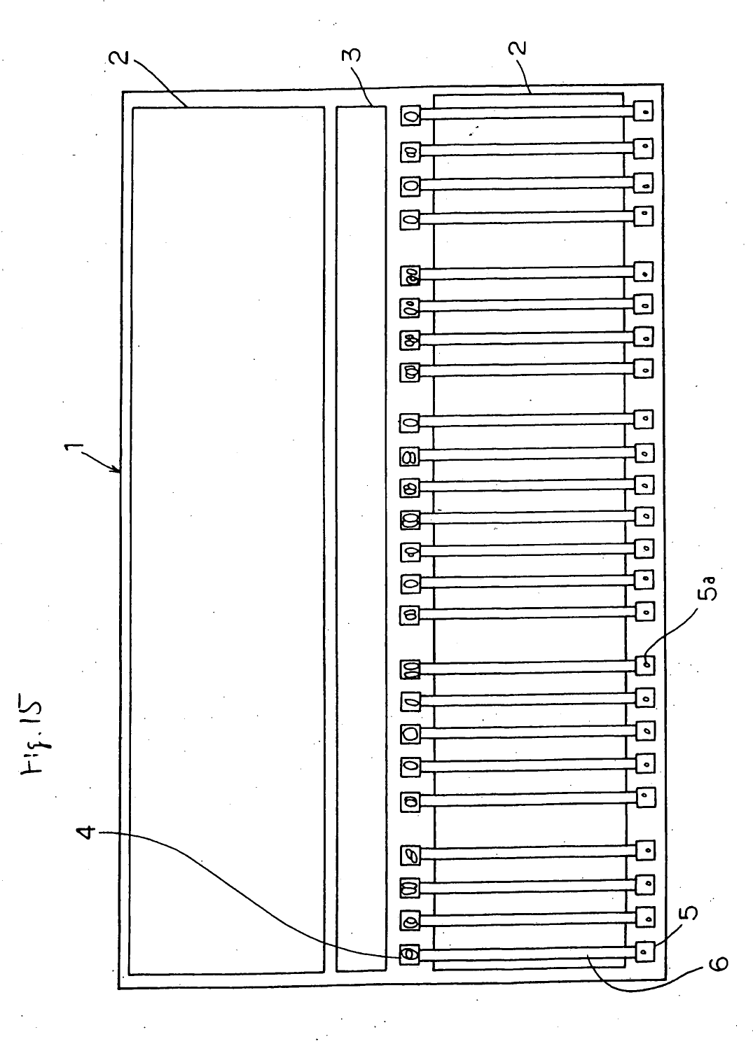

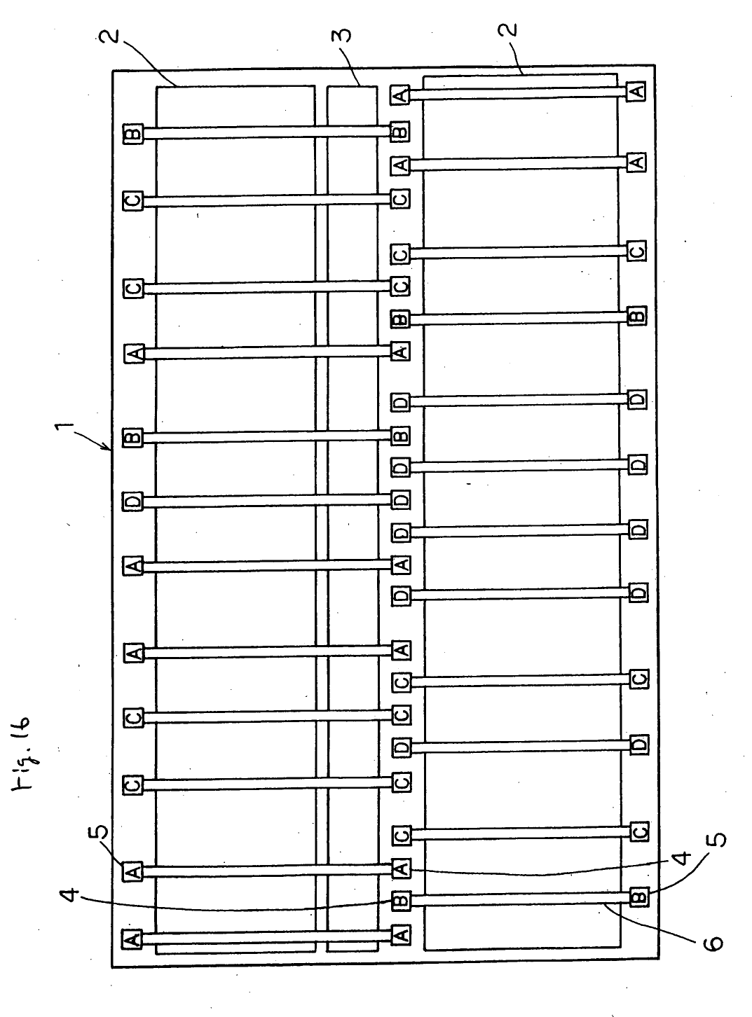

There is no restriction on the arrangement of bonding pads except for the restrictions specified by the package. For example, as is apparent from symbols A to D in FIG. 13, the use of first bonding pads 4 in the central portion of semiconductor device 1 may be different from the use of second bonding pads 5 in the edge portion of semiconductor device 1 and which are arranged so as to correspond to first bonding pads 4. Further, in the embodiment shown in FIG. 5, first bonding pads 4 in the central portion of semiconductor device 1 and second bonding pads 5 in the edge portion of semiconductor device 1 have the same relative positioning to the X-direction. However, as shown in FIG. 14, the positions of first bonding pads 4 and second bonding pads 5 that are connected by wirings 6 may be mutually shifted in the X-direction in FIG. 14. This embodiment has an advantage in that, when the pad arrangement required by the package that uses pads in the central portion of semiconductor device 1 is different from the pad arrangement required by the package that uses pads in the edge portion of semiconductor device 1, an optimal pad arrangement can be formed for each package. However, when there is no problem with situation in which first bonding pads 4 in the central portion of semiconductor device 1 and second bonding pads 5 in the edge portion of semiconductor device 1, that are connected by wirings 6, are relatively positioned the same to the X-direction, it is convenient to align coordinates of bonding pads 4, 5 in the X-direction, in terms of the following points. A probe card that is designed so that a probe is abutted on bonding pad 4 in the central portion can be used for bonding pads 5 in the edge portion of the same coordinates in the X-direction. Therefore, when a customer requests that few needle traces of the probe remain in bonding pads 5 in the edge portion of semiconductor device 1, and when probe testing is repeated plural times, the probe testing is repeated at bonding pads 4 in the central portion for almost the same number of times, while the probe testing is performed at bonding pads 5 only once. With this operation, as shown in FIG. 15, it is possible to minimize scratches 5a made on bonding pads 5 that will be used by the customer. Therefore, since pads that have fewer scratches due to probe testing can be used for package assembly, bonding becomes easier.

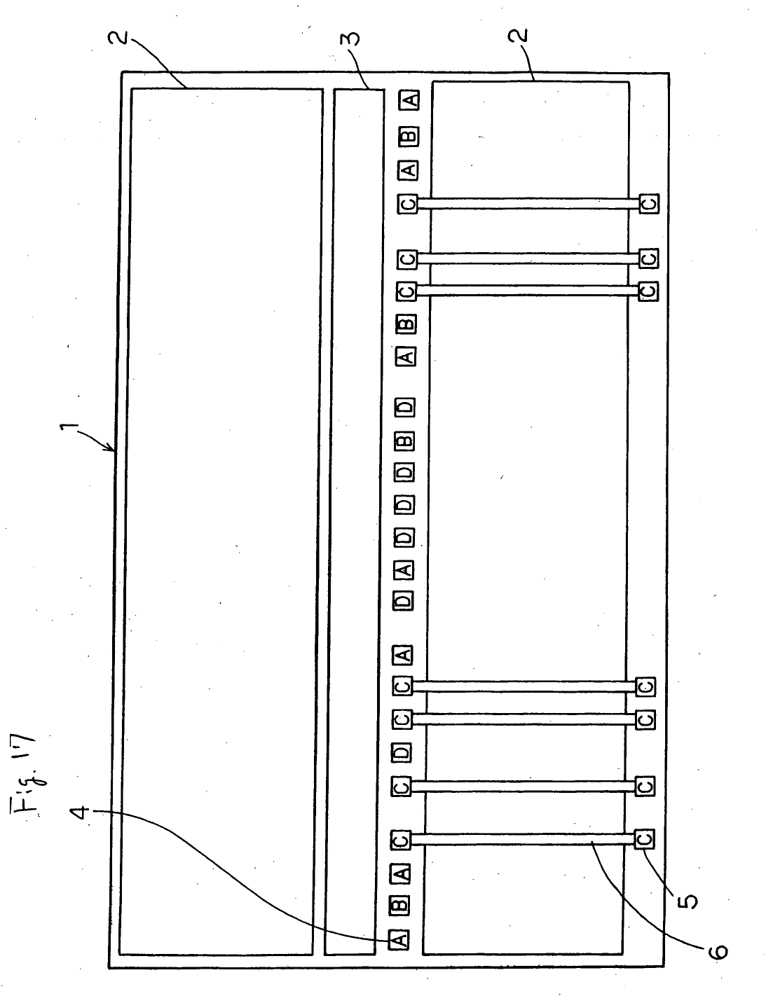

Further, in the embodiment shown in FIG. 5, the plurality of bonding pads 4 is arranged in the central portion of semiconductor device 1, and the plurality of bonding pads 5 is arranged in one edge portion of semiconductor device 1. However, as shown in FIG. 16, bonding pads 5 may be alternately distributed to both edge portions. This embodiment can address a package that requires broad pad intervals in the edge portions.

In the above-mentioned embodiments, it is assumed that all bonding pads arranged in the central portion and edge portions of semiconductor device 1 are connected, however, only some of the bonding pads may be connected. For example, as shown in FIG. 17, only DQ pads (pads of symbol C) are arranged not only in the central portion but also in the edge portion, and the DQ pads in the central portion and in the edge portion are connected by wiring 6. This arrangement is effective on a package in which power source pads (pads of symbols A and B) and address pads (pads of symbol D) may be used in the central portion of semiconductor device 1 and only DQ pads must be used in the edge portion of semiconductor device 1.

While preferred embodiments of the present invention have been described using specific terms, such description is for illustrative purposes only, and it is to be understood that changes and variations may be made without departing from the spirit or scope of the following claims.

What is claimed is:

1. A semiconductor device comprising:
a plurality of first pads for bonding, arranged in a central portion of said semiconductor device;
a plurality of second pads for bonding, arranged in an edge portion of said semiconductor device; and
a wiring for connecting said first pad and said second pad.

2. The semiconductor device according to claim 1, wherein one output circuit is divided in half, and one of said divided output circuits is connected to said first pad, and the other is connected to said second pad.

3. The semiconductor device according to claim 2, further comprising a control circuit for giving the same control signal to each of said divided output circuits.

4. The semiconductor device according to claim 3, wherein said output circuit is MOS-FET.
